(19) United States
(12) Patent Application Publication
(10) Pub. No.: US 2021/0363625 A1
(43) Pub. Date: Nov. 25, 2021

(54) MASK STRIP AND FABRICATION METHOD THEREOF AND MASK PLATE

(71) Applicants: ORDOS YUANSHENG OPTOELECTRONICS CO., LTD., Ordos, Inner Mongolia (CN); BOE TECHNOLOGY GROUP CO., LTD., Beijing (CN)

(72) Inventors: Jian Zhang, Beijing (CN); Chunchieh Huang, Beijing (CN); Zhiming Lin, Beijing (CN); Xinjian Zhang, Beijing (CN); Qi Wang, Beijing (CN); Zhiyuan Hao, Beijing (CN); De Zhang, Beijing (CN); Dejian Liu, Beijing (CN); Zhen Wang, Beijing (CN); Pu Sun, Beijing (CN)

(73) Assignees: ORDOS YUANSHENG OPTOELECTRONICS CO., LTD., Ordos, Inner Mongolia (CN); BOE TECHNOLOGY GROUP CO., LTD., Beijing (CN)

(21) Appl. No.: 16/315,718

(22) PCT Filed: Jan. 23, 2018
(86) PCT No.: PCT/CN2018/073790

§ 371 Date: Jan. 7, 2019

(30) Foreign Application Priority Data
Aug. 25, 2017 (CN) 201710742464.3

(51) Int. Cl. C23C 14/04; C23C 16/04

(52) U.S. Cl. CPC C23C 14/042; C23C 16/042

(57) ABSTRACT

A mask strip, comprising: a plurality of mask units (2) in a first direction; each of the mask units (2) comprising a mask region (3) and a non-mask region (11) surrounding the mask region (3), the non-mask region (11) comprising a side region (4) and an original stress concentration region (6) inside the side region (4); each of the mask units (2) further comprising a stress concentration structure, wherein the stress concentration structure is within a part of the side region (4) other than the original stress concentration region (6). Also discloses a mask plate and a method of fabricating a mask strip.

### CROSS-REFERENCE TO RELATED APPLICATIONS

This application claims benefit of the filing date of Chinese Patent Application No. 201710742464.3 filed on Aug. 25, 2017, the disclosure of which is hereby incorporated by reference.

### TECHNICAL FIELD

This invention relates to display technology, and more particularly, to a mask strip, a method of fabricating the mask strip, and a mask plate.

### BACKGROUND

At present, the organic light-emitting diode (OLED has gradually become a mainstream of display device due to its excellent performance such as low power consumption, high color saturation, wide viewing angle, thin thickness, flexibility and the like. During mass production of OLEDs, a fine metal mask (FMM) is usually used to form an organic light-emitting layer in each pixel unit by vapor deposition technology.

### BRIEF SUMMARY

Accordingly, one example of the present disclosure is a mask strip. The mask strip may comprise a plurality of mask units in a first direction. Each of the mask units may comprise a mask region and a non-mask region surrounding the mask region. The non-mask region may comprise a side region and an original stress concentration region inside the side region. Each of the mask units may further comprise a stress concentration structure. The stress concentration structure may be within a part of the side region other than the original stress concentration region. The side region may be a part of the non-mask region located within a distance smaller than or equal to a first distance to an edge of the mask strip. The original stress concentration region may be a part of the side region located within a distance smaller than or equal to a second distance to the corresponding mask region. The first direction may be a stretching direction.

The stress concentration structure may comprise a plurality of cavities. The cavities may be etching cavities or welding point cavities. In the case of welding point cavities, there may be no overlap between the welding point cavities in the stress concentration structure.

A center of each of the mask units may overlap with a center of the mask region. The stress concentration structure may be located at each of four corners of each of the mask units within the side region. The stress concentration structure may have a rectangular shape, and a length direction of the rectangular shape may be parallel to the first direction. Each of the mask units may comprise 2 or more mask regions, and the mask regions may be arranged in a direction perpendicular to the first direction.

Another example of the present disclosure is a mask plate comprising the mask strip according to one embodiment of the present disclosure.

Another example of the present disclosure is a method of fabricating a mask strip. The method may comprise forming a mask strip body, the mask strip body comprising a plurality of mask units which are arranged in a first direction, each of the mask units comprising a mask region and a non-mask region surrounding the mask region, the non-mask region comprising a side region and an original stress concentration region inside the side region, and forming a stress concentration structure within a part of the side region other than the original stress concentration region. The stress concentration structure may comprise a plurality of cavities arranged in an array mode. The cavities may be welding point cavities.

In one embodiment, forming the stress concentration structure may comprise forming the welding point cavities at positions corresponding to the cavities to be formed at a surface of the mask strip body using a welding equipment. In the step of forming the welding point cavities, an output energy of a welding head of the welding equipment may be 0.1 J to 0.2 J, and a processing time thereof may be 0.5 to 1 milliseconds. The cavities may be etching cavities, and there may be no overlap among the etching point cavities in the stress concentration structure.

In another embodiment, forming the stress concentration structure may comprise forming the etching cavities at positions corresponding to the cavities to be formed at a surface of the mask strip body using an etching liquid.

### BRIEF DESCRIPTION OF THE DRAWINGS

The subject matter which is regarded as the invention is particularly pointed out and distinctly claimed in the claims at the conclusion of the specification. The objects, features, and advantages of the invention are apparent from the following detailed description taken in conjunction with the accompanying drawings in which:

FIG. 1 is a top view of a mask strip according to one embodiment of the present disclosure;

FIG. 2 is a schematic diagram of a side region and an original stress concentration region of a mask unit according to one embodiment of the present disclosure;

FIG. 3 is a schematic view of a mask strip body without a stress concentration structure under a stress simulation test according to one embodiment of the present disclosure;

FIG. 4 is a top view of a mask strip in the prior art;

FIG. 5 is a schematic view of distribution of wrinkle along A-A′ line in FIG. 4;

FIG. 6 is a schematic comparison diagram showing winkle distribution along the A-A′ line of FIG. 1 and the A-A′ line in FIG. 4;

FIG. 7 is a top view of a stress concentration structure according to one embodiment of the present disclosure;

FIG. 8 is a top view of a mask strip according to one embodiment of the present disclosure; and

FIG. 9 is a flowchart of a method for fabricating a mask strip according to one embodiment of the present disclosure.

### DETAILED DESCRIPTION

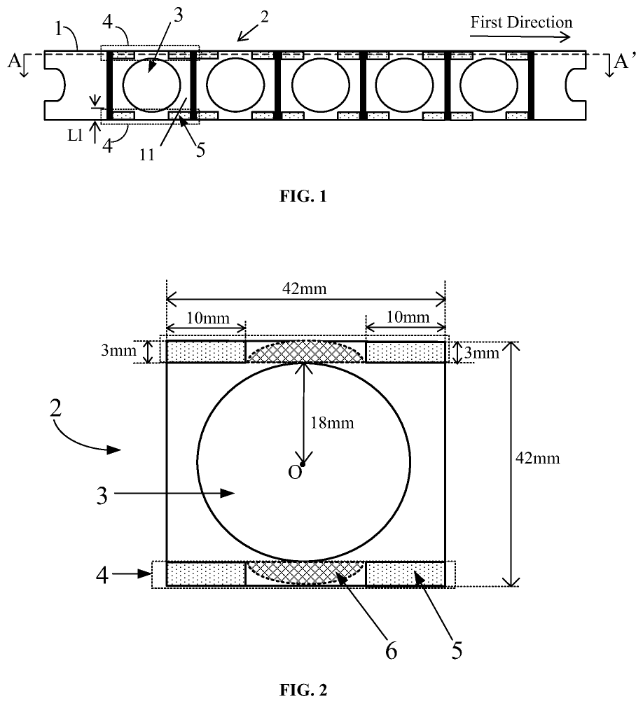

The present disclosure will be described in further detail with reference to the accompanying drawings and embodiments in order to provide a better understanding by those skilled in the art of the technical solutions of the present disclosure. Throughout the description of the disclosure, reference is made to FIGS. 1-9. When referring to the figures, like structures and elements shown throughout are indicated with like reference numerals.

In a process of fabricating a fine metal mask, a pulling force first needs to be applied to two ends of a mask strip to stretch the mask strip. Then, the mask strip is fixed to a fixed frame. As such, the fine metal mask is obtained.

However, when a mask region on the mask strip has an irregular shape, that is, not a rectangular shape, during the process of stretching the mask strip, a side region of the mask strip can generate a large amplitude of wrinkles due to non-uniform stress distribution. When an organic light emitting layer is prepared using the fine metal mask with the mask strip, the distance between the mask region of the mask strip and a display substrate is increased, thereby influencing vapor deposition effect.

FIG. 1 is a top view of a mask strip provided according to one embodiment of the present disclosure. FIG. 2 is a schematic diagram of a side region and an original stress concentration region 6 of a mask unit according to one embodiment of the present disclosure. As shown in FIG. 1 and FIG. 2, the mask strip comprises a mask strip body 1. The mask strip body 1 comprises a plurality of mask units 2 arranged in a first direction, that is, a preset stretching direction. The mask unit 2 comprises a mask region 3 and a non-mask region 11 surrounding the mask region 3. An area of the non-mask region 11 located within a distance smaller than or equal to a first preset distance L1 to an edge of the mask strip is a side region 4. An area of the side region 4 located within a distance smaller than or equal to a second preset distance to the corresponding mask region 3 is an original stress concentration region 6. A stress concentration structure is positioned in at least a part of the side region 4 other than the original stress concentration region 6.

In one embodiment, the mask strip in FIG. 1 is a single-row mask strip. In the single-row mask strip, a mask unit 2 comprises only a mask region 3. All mask regions 3 on the mask strip body 1 are arranged in a preset stretching direction. In one embodiment, the shape of the mask region 3 is circular. The shape of the mark region 3 could be other shapes, and the technical scheme of the disclosure is not limited by this embodiment.

In one embodiment, the first preset distance can be determined based on the size of the mask strip and factors such as the shape of the mask region 3 in the mask strip. As such, a proper side region 4 can be defined.

In one embodiment, without being held to a particular theory, a process and principle of determining a value of the second preset distance are described in detail in the following with reference to the accompanying drawings. FIG. 3 is a schematic view of a mask strip body 1 without a stress concentration structure under a stress simulation test according to one embodiment of the present disclosure. As shown in FIG. 3, a model of a mask strip body 1 without a stress concentration structure is first established through simulation software. Then, a pulling force in the preset stretching direction is applied onto two ends of the mask strip body 1. Stress distribution on the mask strip body 1 is detected through simulation software. In an actual simulation test, a stress concentration region 7 on the mask strip body 1 is located in an area of the non-mask region where the area is relatively narrow in width in a direction perpendicular to the preset stretching direction. The stress at an area of the non-mask region with a relatively wide width in a direction perpendicular to the preset stretching direction is relatively small. Based on this phenomenon, an area in the side region 4 within a distance smaller than or equal to a second preset distance to the corresponding mask region 3 is defined as an original stress concentration region 6. The value of the second preset distance can be determined based on the simulated stress distribution.

Although a certain deviation exists between the original stress concentration region 6 defined as above and the actual stress concentration region 7 in the side region 4 via simulation, the original stress concentration region 6 can reflect actual positions having stress concentration in the side region 4 to a great extent.

The position of the stress concentration structure according to one embodiment of the present disclosure is described in detail below with reference to the accompanying drawings.

In one embodiment, as shown in FIG. 2, each mask unit 2 is a square region with dimensions of 42 mm×42 mm. The mask region 3 is a circular region located in the middle of the mask unit 2. A center of the circular region overlaps with a center of the square region. A radius of the circular region is 18 mm. The value of the first preset distance is 3 mm. The value of the second preset distance based on a simulation test result is 3 mm.

The side regions 4 are rectangular areas having a size of 42 mm×3 mm located above and below the mask region 3. The original stress concentration region 6 is the overlapping area between the side region 4 and a circular area having a radius of 21 mm with a circle center O. After the side region 4 and the original stress concentration region 6 are determined, stress concentration structure can be arranged at least in parts of the side region 4 other than the original stress concentration region 6.

In one embodiment of the present disclosure, the stress concentration structure is arranged in rectangular regions, each having a size of 10 mm×3 mm at two ends of the side region 4. The length direction of the rectangular region is parallel to the preset stretching direction. The stress concentration structure is arranged at the two ends of the side region 4, and the stress concentration structures are arranged at four corners of the mask unit 2. As such, the stress distribution within the side region can be improved. Furthermore, any undesirable effect of the stress concentration structure on a net structure (not shown) in the mask region could be avoided.

Those skilled in the art will appreciate that the situation of the mask unit shown in FIG. 3 presents only one embodiment of the present disclosure as an exemplary role. The technical scheme of the disclosure is not limited herein.

Without being held to a particular theory, the principle of reducing amplitude of wrinkles in the side region 4 of a mask strip according to one embodiment of the present disclosure is described in detail below with reference to the accompanying drawings.

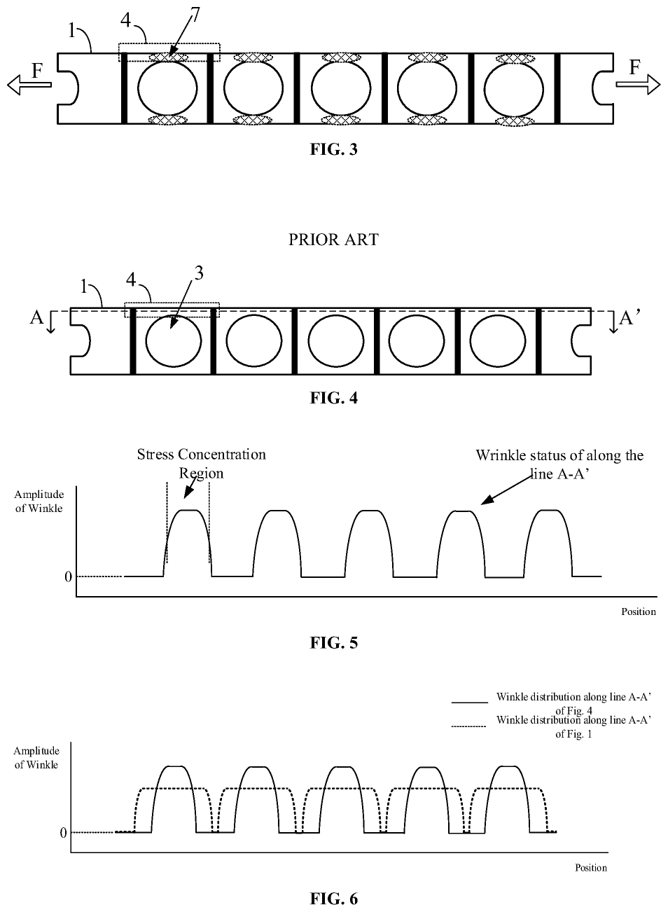

FIG. 4 is a top view of a mask strip in the prior art. FIG. 5 is a schematic diagram of wrinkle distribution along A-A′ line of FIG. 4. As shown in FIG. 4 and FIG. 5, for the side region 4, when two ends of the mask strip in the prior art are stretched, wrinkles only exist in areas having relatively narrow widths in a direction perpendicular to the preset stretching direction, that is, the original stress concentration regions 6. Furthermore, the amplitude of the wrinkles is large.

FIG. 6 is a schematic comparison diagram showing winkle distribution along the A-A′ line of FIG. 1 and the A-A′ line in FIG. 4. As shown in FIG. 6, for the present disclosure, after a pulling force in a preset stretching direction is applied onto two ends of the mask strip body 1, due to the presence of the stress concentration structures, the stress in regions corresponding to the stress concentration structure is increased, that is, the stress is concentrated. However, the stress in the original stress concentration regions 6 is reduced. Compared with the prior art, in the technical scheme of the present disclosure, an area of the stress concentration region in the side region 4 is increased. In other words, stress distribution in the side region 4 is more uniform. As such, the area having wrinkles in the side region 4 is increased, but the amplitude of the wrinkles is reduced.

When using fine metal mask having mask strips according to one embodiment of the present disclosure to prepare an organic light-emitting layer, because wrinkle amplitude is reduced, the distance between the mask region 3 of the mask strip and a display substrate is reduced, thereby improving vapor deposition effect.

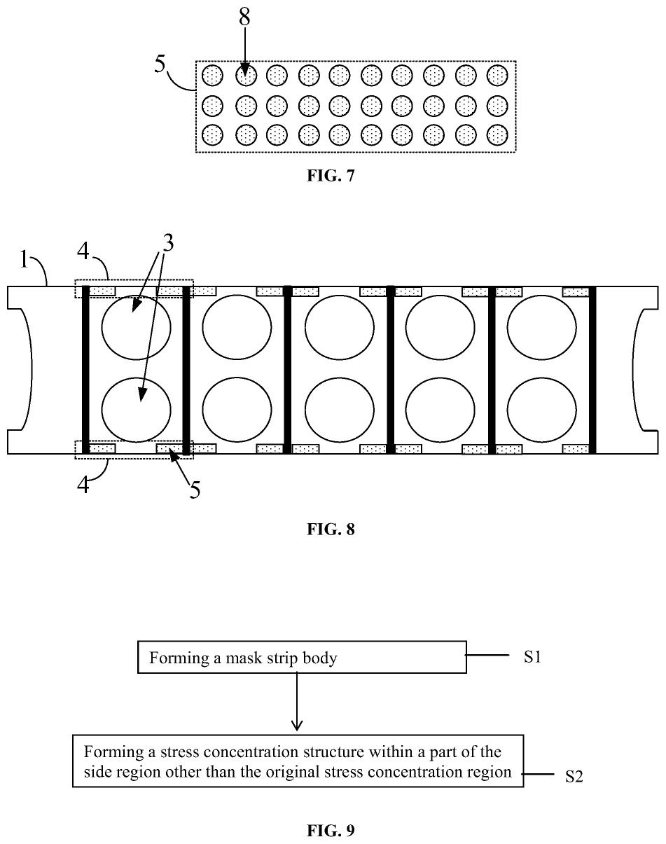

FIG. 7 is a top view of a stress concentration structure according to one embodiment of the present disclosure. As shown in FIG. 7, the stress concentration structure comprises a plurality of cavities 8 arranged in an array mode. Due to the plurality of cavities, when the mask strip body 1 is stretched, stress of the mask strip body 1 is concentrated around the cavities 8. When the plurality of the cavities 8 forms an array, a stress concentration region is formed.

In one embodiment, cavity 8 may be an etching cavity or a welding point cavity. The etching cavity may be formed through a half-etching process. The welding point cavity can be formed through a spot welding process.

When a welding head is utilized to form a welding point cavity on the surface of the mask strip, if adjacent welding point cavities overlap, the mask strip may deform due to the fact that the welding points are too dense. According to one embodiment of the present disclosure, to avoid deforming mask strip in spot welding process, there is no overlap between welding point cavities in the stress concentration structure.

The above stress concentration structure comprising cavities 8 is only one embodiment of the present disclosure. The cavities 8 can achieve a stress concentration function while hardness of the mask strip is not affected. The stress concentration structure can also be of other structures such as a hole, a notch, a step etc, and are not repeated herein.

FIG. 8 is a top view of a mask strip according to one embodiment of the present disclosure. As shown in FIG. 8, the mask strip in this embodiment is a double-row mask strip. That is, one mask unit 2 comprises two mask regions 3. The two mask regions 3 are arranged in the mask units 2 along a direction perpendicular to the preset stretching direction. Stress concentration structure is positioned at least in parts of the side regions 4 at the lower side and upper side of the mask unit other than the original stress concentration regions 6.

In one embodiment, the number of mask regions 3 in each mask unit 2 may be three or more. The mask regions 3 in the mask unit 2 are arranged in the direction perpendicular to the preset stretching direction. Furthermore, the shape of the mask region 3 is not limited to a circle. It may also be other regular shapes or irregular shapes. The specific situation is not described in detail herein.

A mask strip is provided according to embodiments of the present disclosure as mentioned above. The mask strip comprises a mask strip body. Stress concentration structure is arranged at least in parts of side regions of the mask strip body other than the original stress concentration region. As such, stress distribution within the side regions is more uniform when the mask strip is stretched. As a result, the amplitude of wrinkles within the side region is effectively reduced, thereby improving vapor deposition effect.

FIG. 9 is a flow chart of a method of fabricating a mask strip according to one embodiment of the present disclosure. As shown in FIG. 9, the fabrication method can be used for fabricating the mask strips mentioned in the above embodiments of the present disclosure. The method comprises the following steps:

In step S1, a mask strip body is formed.

The mask strip body comprises a plurality of mask units which are arranged in a first direction, that is, a preset stretching direction. The mask unit comprises a mask region and a non-mask region surrounding the mask region. An area of the non-mask region located within a distance smaller than or equal to a first preset distance to an edge of the mask strip is a side region. An area of the side region located within a distance smaller than or equal to a second preset distance to the corresponding mask region is an original stress concentration region.

In one embodiment, the mask strip body is made of invar steel so that the mask strip body has relatively high toughness and plasticity.

In step S2, stress concentration structure is arranged at least in parts of the side regions other than the original stress concentration regions.

In one embodiment, the stress concentration structure comprises a plurality of cavities arranged in an array mode. The cavity may be a welding point cavity or an etching cavity.

In one embodiment, when the cavity is a welding point cavity, the method of forming a stress concentration structure comprises the following step: welding point cavities are formed at positions corresponding to the cavities to be formed at a surface of the mask strip body by using welding equipment. In the process of forming welding point cavities, if output energy of the welding head is too small or if the processing time is too short, the welding point cavities are difficult to form. If the output energy of the welding head is too large, or if the processing time is too long, the mask strip can be easily deformed. In a process of forming welding point cavities according to one embodiment of the present disclosure, the output energy of the welding head is 0.1 J-0.2 J. The processing time thereof is 0.5-1 milliseconds. As such, the welding point cavities may be formed on the mask strip without deforming the mask strip.

In another embodiment of the present disclosure, the welding point cavities in the stress concentration structure do not overlap, thereby effectively preventing the mask strip from being deformed to a certain degree.

In one embodiment, when the cavity is an etching cavity, the step of forming a stress concentration structure comprises the following step: etching cavities are formed in positions corresponding to the cavities to be formed at a surface of the mask strip body through etching liquid.

Another example of the present disclosure is a mask plate. The mask plate comprises a mask strip according to one embodiment of the present disclosure. The mask strip may be the mask strip in the above embodiments of the present disclosure. The specific structure can be found in the description of the embodiments mentioned above and is not repeated herein.

In one embodiment, when fabricating the mask plate, the stress concentration structure may be formed first on the mask strip body. Then, the mask strip with the stress concentration structure may be welded and fixed onto a fixed frame. In another embodiment, mask strips are first welded and fixed with the fixed frame, and then stress concentration structure is formed on the mask strip body. In one embodiment, a method for forming a stress concentration structure first and welding and fixing later is adopted.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A mask strip, comprising:
a plurality of mask units in a first direction;
each of the mask units comprising a mask region and a non-mask region surrounding the mask region, the non-mask region comprising a side region and an original stress concentration region inside the side region;
each of the mask units further comprising a stress concentration structure,
wherein the stress concentration structure is within a part of the side region other than the original stress concentration region.

2. The mask strip according to claim 1, wherein the side region is a part of the non-mask region located within a distance smaller than or equal to a first distance to an edge of the mask strip.

3. The mask strip according to claim 1, wherein the original stress concentration region is a part of the side region located within a distance smaller than or equal to a second distance to the corresponding mask region.

4. The mask strip according to claim 1, the first direction is a stretching direction.

5. The mask strip according to claim 1, wherein the stress concentration structure comprises a plurality of cavities.

6. The mask strip according to claim 5, wherein the cavities are etching cavities.

7. The mask strip according to claim 5, wherein the cavities are welding point cavities.

8. The mask strip according to claim 7, wherein there is no overlap between the welding point cavities in the stress concentration structure.

9. The mask strip according to claim 1, wherein a center of each of the mask units overlaps with a center of the mask region, and the stress concentration structure is located at each of four corners of each of the mask units within the side region.

10. The mask strip according to claim 1, wherein the stress concentration structure has a rectangular shape, and a length direction of the rectangular shape is parallel to the first direction.

11. The mask strip according to claim 1, wherein each of the mask units comprises 2 or more mask regions, and the mask regions are arranged in a direction perpendicular to the first direction.

12. A mask plate comprising the mask strip according to claim 1.

13. A method of fabricating a mask strip, the method comprising:
forming a mask strip body, the mask strip body comprising a plurality of mask units which are arranged in a first direction, each of the mask units comprising a mask region and a non-mask region surrounding the mask region, the non-mask region comprising a side region and an original stress concentration region inside the side region, and
forming a stress concentration structure within a part of the side region other than the original stress concentration region.

14. The method according to claim 13, wherein the stress concentration structure comprises a plurality of cavities arranged in an array mode.

15. The method according to claim 14, wherein the cavities are welding point cavities.

16. The method according to claim 15, wherein forming the stress concentration structure comprises:
forming the welding point cavities at positions corresponding to the cavities to be formed at a surface of the mask strip body using a welding equipment.

17. The fabrication method according to claim 16, wherein in the step of forming the welding point cavities, an output energy of a welding head of the welding equipment is 0.1 J to 0.2 J, and a processing time thereof is 0.5 to 1 milliseconds.

18. The fabrication method according to claim 14, wherein the cavities are etching cavities, and there is no overlap among the etching point cavities in the stress concentration structure.

19. The fabrication method according to claim 18, wherein forming the stress concentration structure comprises:
forming the etching cavities at positions corresponding to the cavities to be formed at a surface of the mask strip body using an etching liquid.
